(19) United States
(12) Patent Application Publication
(10) Pub. No.: US 2007/0223543 A1
(43) Pub. Date: Sep. 27, 2007

(54) Laterally Implanted Electroabsorption Modulated Laser

(76) Inventors: Kelvin Prosyk, Ontario (CA); Joan Haysom, Ontario (CA)

Correspondence Address: MARK D. SARALINO (GENERAL);RENNER, OTTO, BOISSELLE & SKLAR, LLP, 1621 EUCLID AVENUE, NINETEENTH FLOOR, CLEVELAND, OH, 44115-2191, US

(21) Appl. No.: 11/569,385

(22) PCT Filed: May 20, 2005
(86) PCT No.: PCT/CA05/00781

§ 371 Date: Mar. 7, 2007

Related U.S. Application Data
(60) Provisional application No. 60/572,610, filed on May 20, 2004.

(30) Foreign Application Priority Data
Nov. 2, 2004 (GB) 0424253.3

(51) Int. Cl. H01S 5/026; G02F 1/015

(52) U.S. Cl. 372/26; 385/2

(57) ABSTRACT

A monolithically integrated electroabsorption modulated laser having a ridge waveguide structure, has lateral ion implantation. The integrated device has a laser section and a modulator section. The modulator section has ion implanted regions adjacent to the waveguide ridge. The implanted regions penetrate through the top cladding layer to reduce capacitance within the intrinsic active core of the reverse biased modulator and allow a shallow etched ridge waveguide structure to be used for the modulator. The device provides good optical coupling, efficient manufacturing, and good high power performance.

### CROSS-REFERENCE TO RELATED APPLICATIONS

This is the first application filed for the present invention.

### MICROFICHE APPENDIX

Not Applicable.

### TECHNICAL FIELD

The present invention relates to the field of photonics and the construction of lasers and electroabsorption modulators, and more particularly with the construction of a monolithically integrated electroabsorption modulated laser.

### BACKGROUND OF THE INVENTION

Electroabsorption modulators (EAMs) provide a convenient and efficient way of modulating optical communications signals, especially those generated by laser sources. Combining a laser and an EAM into a monolithically integrated electroabsorption modulated laser (EML) can reduce manufacturing costs, assembly costs and footprint. An important consideration in monolithically integrating a laser and modulator on a single waveguide is that there must be good optical coupling between the two sections—there must be a good overlap between their optical modes.

The EAM section of EMLs known in the art generally comprise deeply etched waveguides in one form or another. Etching deep is traditionally necessary in order to electrically disconnect the upper cladding layer from the rest of the chip in order to reduce capacitance of the EAM. In such devices, the top electrical contact to the modulator is only in contact with the upper region of the waveguide and thus the modulator has a low capacitance.

Traditional EMLs also generally adopt a buried heterostructure (BH) format for the deeply etched laser because it offers low threshold current and high efficiency. However, this generally requires the modulator to also be deeply etched and to use a buried waveguide format to avoid optical coupling problems between the laser and EAM sections. This format also suits the buried SI—InP style of EAM quite well, since the optical modes of the laser and EAM sections match laterally and the overgrowth used to bury them can be done in a single step for both. A drawback to the BH laser format, however, can be lower output power, poor reliability and more complexity of manufacture when compared to a ridge wave guide (RWG) laser format.

Some traditional EMLs have EA sections that are deeply etched to the top of the waveguide core. For example, Noda et al., Journal of Lightwave Technology, Vol. LT-4, No. 10, October 1986, teaches an EAM section deeply etched to the top of the waveguide core to form a strip loaded EAM.

Other EMLs have EA sections deeply etched past the waveguide core, for example, Kawamura et al., IEEE Journal of Quantum Electronics, vol. QE-23, no. 6, June 1987, teaches monolithic integration of a distributed feedback laser with a deeply etched optical modulator. The integrated device is constructed using a hybrid growth technique wherein the laser is grown with liquid phase epitaxy in a BH configuration and the modulator is grown on the same substrate but with separate steps, using molecular beam epitaxy to produce a multiquantum well (MQW) modulator which is then deeply etched, so that the etching continues past the waveguide core. This device has a disadvantage of the BH configuration as well as requiring many discrete process steps to produce the laser and the modulator separately. Other possible disadvantages include limited modulation efficiency and less than ideal coupling between the laser and EAM, due to the hybrid growth technique.

Still other EMLs have EA sections deeply etched and then buried in semi-insulating (SI) InP. For example Tanaka et al., Journal of Lightwave Technology, vol. 8(9), p. 1357, 1990, teaches an EAM section deeply etched and then buried in SI—InP.

Aoki et al., IEEE journal of Quantum Electronics, Vol. 29(6), p. 2088, 1993, teaches a BH laser monolithically integrated with a BH MQW EAM. Here, both the laser and EAM are of a BH configuration and can benefit from common process steps in manufacture but still have the disadvantages of the BH configuration.

A ridge waveguide (RWG) laser could provide output power benefits over deep etched and BH lasers, but the shallow etch required for a RWG laser would be incompatible with the deep etch required for traditional EAMs. This incompatibility might possibly be overcome by a carefully managed shallow-to-deep etched transition region between the laser and the EAM to minimize back reflections into the laser. Disadvantages of this possible solution include increased. costs for the extra processing steps of separate etches for the laser and the EAM, a deep etch and burial-overgrowth for the laser, and stringent manufacturing tolerances required for the transition region.

It would be advantageous to have an EML that could be operated at high output power. Accordingly, an improved monolithically integrated electroabsorption modulated laser (EML) remains highly desirable.

### SUMMARY OF THE INVENTION

It is therefore an object of the present invention to provide an improved monolithically integrated electroabsorption modulated laser (EML). In particular, it is an object of the present invention to provide a monolithically integrated electroabsorption modulated laser wherein the modulator is of shallow etched ridge waveguide design by using ion implantation of the etched upper cladding layer to reduce capacitance of the modulator.

It is another object of the present invention to provide an electroabsorption modulator of shallow etched ridge waveguide design, the modulator thus being suited to monolithic integration with a shallow etched ridge waveguide laser.

Accordingly, an aspect of the present invention provides an optoelectronic semiconductor device adapted for reverse-biased operation. The optoelectronic semiconductor device has a semiconductor substrate, an active layer on the substrate and a conductive layer on the active layer. The conductive layer has etched regions, wherein said etched regions cover the active layer and the etched regions are ion implanted to reduce capacitance.

In some embodiments, the optoelectronic semiconductor device is a shallow etched ridge waveguide electroabsorption modulator.

In some embodiments, the optoelectronic semiconductor device is monolithically integrated with a laser.

In some embodiments, the active layer of the modulator is optically aligned with an active layer of the laser.

In some embodiments, the active layer of the modulator is shared by the laser.

In some embodiments, the laser is a distributed feedback laser.

Another aspect of the present invention provides an integrated optoelectronic semiconductor device having a semiconductor substrate, a ridge waveguide laser on the substrate, and a shallow etched ridge modulator on the substrate, integrated with the laser. The laser has an active layer. The modulator has an active layer adapted to accept optical energy from the laser. The modulator has a conductive layer on the active layer. The conductive layer has a ridge defined by etched regions of the modulator adjacent the ridge and the etched regions adjacent the ridge are ion implanted to reduce capacitance.

In another embodiment, the etched regions of the modulator are substantially aligned with the sides of the ridge.

In another embodiment, the etched regions of the modulator are spaced from the ridge.

In another embodiment, the etched regions of the modulator undercut the ridge.

In other embodiments, the modulator is an electroabsorption modulator.

In other embodiments, the laser is a distributed feedback laser.

In some embodiments, the active layer of the laser is similar to the active layer of the modulator.

In some embodiments, the laser and the modulator have similar ridge waveguide geometry.

In some embodiments, the laser and the modulator have similar epitaxial structure.

In some embodiments, the active layer of the laser comprises a single well structure.

In other embodiments, the active layer of the laser comprises a multiple quantum well structure.

Yet another aspect of the present invention provides a method of reducing capacitance of an optoelectronic semiconductor device adapted for reverse-biased operation, the semiconductor device having a semiconductor substrate, an active layer on the substrate and a conductive layer on the active layer, the conductive layer having etched regions, wherein said etched regions cover the active layer. The method comprises a step of implanting ions in the etched regions.

In other embodiments, the ions are implanted through the entire depth of the etched regions of the conductive layer and in still other embodiments, the ions are further implanted through the active layer.

In some embodiments, the ions are inert ions.

In some embodiments, the ions are hydrogen ions.

In other embodiments, the ions are helium ions.

In some embodiments, the method comprises a plurality of implanting steps, each having a different implant acceleration energy.

In some embodiments, the method comprises three consecutive implanting steps of increasing implant acceleration energy.

Still another aspect of the present invention provides an optoelectronic device having a semiconductor substrate, an active layer on the substrate and a doped layer on the active layer. The doped layer has a ridge adapted to guide optical energy in the active layer. The ridge is defined by adjacent etched regions of the doped layer. At least a portion of the doped layer is adapted for reverse-biased operation and the etched regions within that portion of said doped layer are ion implanted to reduce capacitance.

In some embodiments, the etched regions of the doped layer are shallow etched.

In some embodiments, the portion of the optoelectronic device adapted for reverse-biased operation comprises an electroabsorption modulator.

In some embodiments, the optoelectronic device further comprises a laser.

In some embodiments, the modulator and the laser of the optoelectronic device are monolithically integrated.

In some embodiments, the laser is a distributed feedback laser.

In some embodiments, the active layer of the laser, and the active layer of the modulator have a common epitaxial structure.

In some embodiments of the optoelectronic device, the active layer of said laser comprises a single well structure.

In other embodiments of the optoelectronic device, the active layer of said laser comprises a multiple quantum well structure.

A further aspect of the present invention provides an integrated optical device, having a laser section adapted to produce optical energy, and a modulator section monolithically integrated with the laser section. The modulator has an active layer and a doped layer on the active layer. The doped layer has a shallow etched ridge which is defined by adjacent etched regions of the doped layer. The ridge is adapted to guide the optical energy within said active layer. The modulator is adapted to modulate the optical energy. The adjacent etched regions are ion implanted to reduce capacitance of the adjacent etched regions.

Further features and advantages of the present invention will become apparent to those skilled in the art from the following detailed description of specific embodiments of the invention taken in combination with the appended drawings.

### BRIEF DESCRIPTION OF THE DRAWINGS

Embodiments of the present invention will now be described, by way of example only, with reference to the appended drawings, in which:

FIG. 1 is a schematic illustration showing a prior art deeply etched optoelectronic device;

FIG. 2 is a schematic illustration of a prior art buried heterostructure optoelectronic device;

FIG. 3 is a schematic illustration of a prior art shallow etched, weakly guided, optoelectronic device;

FIG. 4 is an schematic illustration of a shallow etched, weakly guided EAM with lateral ion implantation, according to an embodiment of the present invention; and

FIG. 5 is an isometric illustration of a monolithically integrated electroabsorption modulated laser with lateral ion implantation, according to an embodiment of the present invention.

It will be noted that, throughout the appended drawings, like features are identified by like reference numerals.

### DETAILED DESCRIPTION OF THE PREFERRED EMBODIMENT

Generally, the present invention provides a monolithically integrated electroabsorption modulated laser wherein the modulator is of shallow etched ridge waveguide design which uses ion implantation of the etched upper cladding layer to reduce capacitance of the modulator.

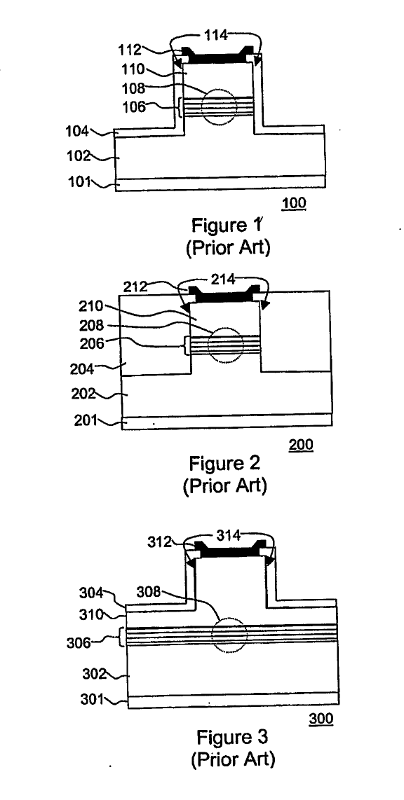

FIG. 1 is a simplified illustration of a prior art deeply etched optoelectronic device 100. FIG. 1 can represent a semiconductor laser or an electroabsorption modulator (EAM). A laser or an EAM are constructed of similar materials, but would differ in design details and operation. The device of FIG. 1 will now be described as an EAM 100. The EAM 100 is deeply etched. It comprises a semiconductor substrate 101, an active layer 106, followed by an upper cladding layer 110 and a metal electrode 112. The optical mode 108 is approximately centered around the active layer 106 which functions as a vertical waveguide. The horizontal waveguide function is provided by the deeply etched ridge of material bounded by the vertical sides 114 which are created by deeply etching the top cladding layer 110, the active layer 106 and part of the lower cladding layer 102. An insulating layer 104 of polyimide for example may also be applied. The EAM 100 operates in a reverse biased mode by application of a negative voltage applied to the electrode 112, with respect to the substrate 101. Varying the bias voltage controls the amount of optical energy the active layer 106 will absorb, thus modulating the optical energy. In a well known doping pattern, the lower cladding layer 102 is n-doped and the upper cladding layer 110 is p-doped and the active layer 106 can be termed the intrinsic layer. In MQW EAMs, the active layer 106 can comprise multiple layers.

FIG. 2 is a simplified illustration of a prior art buried heterostructure (BH) optoelectronic device 200. The device of FIG. 2 will now be described as an EAM 200. The BH EAM 200 is also deeply etched. It comprises a semiconductor substrate 201, an active layer 206, followed by an upper cladding layer 210 and a metal electrode 212. The optical mode 208 is approximately centered around the active layer 206 which functions as a vertical waveguide. The horizontal waveguide function is provided by the deeply etched ridge of material bounded by the vertical sides 214 which are created by deeply etching the top cladding layer 210, the active layer 206 and part of the lower cladding layer 202. In this device, the deeply etched ridge is buried in a semiconductor material 204.

FIG. 3 is a simplified illustration of a prior art shallow etched, weakly guided, optoelectronic device 300. The device of FIG. 3 will now be described as an EAM 300. The EAM 300 is shallow etched. It comprises a semiconductor substrate 301, an active layer 306, followed by an upper cladding layer 310 and a metal electrode 312. The optical mode 308 is approximately centered around the active layer 306 which functions as a vertical waveguide. A weakly guided horizontal waveguide function is provided by the shallow etched ridge of material bounded by the vertical sides 314 which are created by shallow etching part of the top cladding layer 310 only. An insulating layer 304 of polyimide for example may also be applied. The optical mode 308 is substantially below the bottom of the etch. In EAMs constructed in this manner, there is no electrical confinement in the upper cladding layer 310 and therefore the modulator's electrode 312 electrically connects with the remaining upper cladding layers 310 beside the waveguide thus creating a substantial capacitance across the active layer 306. This can cause a considerable problem to high frequency drive signals applied to the electrode 312 of the modulator 300.

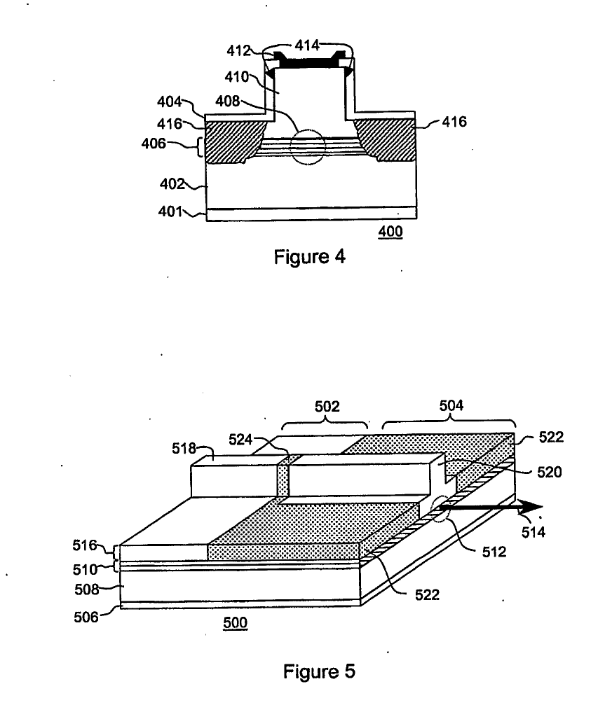

The present invention allows a useful EAM to be constructed as a shallow etched device, by providing electrical confinement in the upper cladding by the use of ion implantation. This EAM is well adapted for monolithic integration with a shallow etched ridge waveguide laser. With reference to FIG. 4, an embodiment of the present invention is illustrated in simplified form as a shallow etched, weakly guided EAM 400. EAM 400 comprises a semiconductor substrate 401, an active layer 406, followed by an upper cladding layer 410 and a metal electrode 412. The optical mode 408 is approximately centered around the active layer 406 which functions as a vertical waveguide. A weakly guided horizontal waveguide function is provided by the shallow etched ridge of material bounded by the vertical sides 414 which are created by shallow etching part of the top cladding layer 410 only. The optical mode 408 is substantially below the bottom of the etch. In this case, electrical confinement is provided by ion implanted regions 416, thus greatly reducing the otherwise substantial capacitance of a shallow etched EAM configuration. In one embodiment, an insulating layer 404 of polyimide for example may also be applied. It is important that the implanted regions 416 penetrate through the top cladding layer 410. The implanted regions 416 are shown here also penetrating the active region 406 and partially into the lower cladding region 402, but this is not required. In the embodiment shown in FIG. 4, the inside edges of the regions 416 have a jagged profile.

Ion implantation is known in the art, but for very different purposes. For example Q. Z. Liu et al., Journal of Electronic Materials, Vol. 24(8), p. 991, 1995, discloses a processing technique to fabricate planar InGaAsP/InP electroabsorption waveguide modulators. Lateral ion implantation is used on a strain guided device specifically to confine the electric field between adjacent modulators.

The present invention offers advantages of using a shallow etched waveguide for an EAM, such as simplicity of design, compatibility with shallow etched waveguide lasers, thereby permitting good optical coupling between the laser and the modulator. Reliability is also improved because fewer regrowth surfaces are required and typically lossy burying materials are not required, as compared to deeply etched and BH devices. Another advantage is that heat dissipation for shallow etched waveguides is very good.

FIG. 5 shows a simplified isometric illustration of another embodiment of the present invention. A shallow etched monolithically. integrated electroabsorption modulated laser (EML) 500 comprises a laser section 502 and a modulator section 504, fabricated on a common substrate 506 and a common lower cladding layer 508. An intrinsic active layer 510 provides a vertical waveguide for optical energy created in the laser section 502. A weakly guided horizontal waveguide function is provided by shallow etched ridge 518 in the laser section 502 and by shallow etched ridge 520 in the modulator section 504. Ridge 518 and ridge 520 can be etched from the upper cladding layer 516 in a single operation during construction, ensuring alignment and good optical coupling between the laser section and the modulator section. The optical mode 512 is approximately centered around the active layer 510 and below the ridge 518 and ridge 520. The optical energy exiting the EML 500 is represented here by as arrow 514. The active layer 510 is illustrated as a uniform structure having a common epitaxial structure. The active layer 510 can optionally comprise multiple quantum wells. In another embodiment, a section of the active layer 510 within the laser section 502 can have a different composition than the section of the active layer 510 within the modulator section 504. For example, an enhanced selective area growth technique can be use a single growth for both sections, but one of the sections can then be enhanced using an oxide mask to form a different composition.

Within the modulator section 504 of the EML 500, areas of the upper cladding layer 516 adjacent to the ridge 520 are implanted with ions to create ion implanted regions 522. This serves to dramatically reduce capacitance within active layer 510 of the modulator section 504, and allow the use of a shallow etched ridge waveguide design for an electroabsorption modulator. This, in turn allows the modulator to be easily integrated with a shallow etched ridge waveguide laser. In FIG. 5, the boundaries of the regions 522 have been simplified for illustration purposes and are shown as being straight. In the embodiment of FIG. 5, the regions 522 are spaced from the ridge 520. In another embodiment, the regions 522 undercut the ridge 520. In a further embodiment, the regions 522 are substantially aligned with the ridges 520.

The ion implantation of regions 522 can be performed vertically into the top of the EML 500 using processes well known in the art, by applying a silicon dioxide mask symmetrically aligned with the ridge 520. The implantation mask is typically wider than the ridge 520, so that the implantation, which tends to undercut the mask, does not significantly enter the waveguide, which could cause optical losses. The implantation step can be performed either before or after the ridge etching step. Ion implantation is performed in one or more steps using different implant acceleration energies to control the implantation depth and the uniformity of the ion implantation. Ion implantation is done with inert ions such as hydrogen or helium ions.

The laser section 502 operates in a forward biased mode and the modulator section 504 operates in a reverse biased mode, thus the two sections require electrical isolation. A section 524 of the continuous ridge 518, 524, 520 is also implanted with ions, to provide the required electrical isolation. In other embodiments, the electrical isolation can be provided by a physical gap between ridge 518 of the laser section and ridge 520 of the modulator section. For simplicity of illustration, electrical contact pads, bonding pads and other details of modulator and laser construction have been omitted from FIG. 5.

Using the same etch for the laser and modulator removes one of the etch steps and consequently several processing steps. Also avoiding the need to bury the structure avoids several other processing steps.

The illustrated embodiments describe an electroabsorption type modulator. The present invention however, applies to other types of modulators such as Mach Zehnder modulators, phase modulators or electroabsorption-like devices such as self-electro-optic devices.

The embodiment(s) of the invention described above is(are) intended to be exemplary only. The scope of the invention is therefore intended to be limited solely by the scope of the appended claims.

1.-44. (canceled)

45. An optoelectronic semiconductor device adapted for reverse-biased operation, comprising:
a semiconductor substrate;
an active layer on the substrate; and
a conductive layer on the active layer, having shallow etched regions, wherein said shallow etched regions define a ridge waveguide, and wherein at least a portion of said shallow etched regions is ion implanted creating implanted regions which are substantially aligned with the sides of the ridge, such that the capacitance of the device is reduced.

46. An optoelectronic semiconductor device as claimed in claim 45, comprising an electroabsorption modulator.

47. An optoelectronic semiconductor device as claimed in claim 46, wherein the semiconductor device further comprises a monolithically integrated laser, such that the electroabsorption modulator is in optical communication with the laser.

48. An optoelectronic semiconductor device as claimed in claim 47, wherein the semiconductor device further comprises a monolithically integrated semiconductor optical amplifier, such that the electroabsorption modulator is in optical communication with the laser and/or the semiconductor optical amplifier.

49. An optoelectronic semiconductor device as claimed in claim 48, wherein the active layer of the modulator is optically aligned with an active layer of the laser and/or the semiconductor optical amplifier.

50. An optoelectronic semiconductor device as claimed in claim 49, wherein the active layer of the modulator is shared by the laser and/or semiconductor optical amplifier.

51. An optoelectronic semiconductor device as claimed in claim 50, wherein the laser is a distributed feedback laser.

52. An optoelectronic semiconductor device as claimed in claim 47, wherein; the laser section is adapted to produce optical energy; and the modulator section wherein the conductive layer comprises a doped layer, said doped layer having a shallow etched ridge, said ridge defined by adjacent partially etched regions of said doped layer, said ridge adapted to guide said optical energy within the active layer, said modulator adapted to modulate said optical energy.

53. An integrated optoelectronic semiconductor device comprising:
a semiconductor substrate;
a ridge waveguide laser on the substrate, the laser having an active layer;
a shallow etched ridge modulator on the substrate, the modulator comprising:
an active layer adapted to accept optical energy from the laser; and
a conductive layer on the active layer, the conductive layer having a ridge defined by shallow etched regions of the modulator adjacent the ridge, wherein the shallow etched regions adjacent the ridge are ion implanted such that the capacitance of the device is reduced.

54. An integrated optoelectronic semiconductor device comprising:
a semiconductor substrate;
a semiconductor optical amplifier on the substrate, the semiconductor optical amplifier having an active layer; and
a shallow etched ridge modulator on the substrate, the modulator comprising:
an active layer adapted to be in optical communication with the semiconductor optical amplifier; and
a conductive layer on the active layer, the conductive layer having a ridge defined by shallow etched regions of the modulator adjacent the ridge, the shallow etched regions adjacent the ridge are ion implanted creating implanted regions such that the capacitance of the device is reduced.

55. An integrated optoelectronic semiconductor device as claimed in claim 53 further comprising:
a semiconductor optical amplifier on the substrate, the semiconductor optical amplifier having an active layer in optical communication with the modulator and/or laser

56. An integrated optoelectronic semiconductor device as claimed in claim 53, wherein the implanted regions are substantially aligned with the sides of the ridge.

57. An integrated optoelectronic semiconductor device as claimed in claim 53, wherein the implanted regions are spaced from the ridge.

58. An integrated optoelectronic semiconductor device as claimed in claim 53, wherein the implanted regions undercut the ridge.

59. An integrated optoelectrical semiconductor device as claimed in claim 57 wherein the implanted regions are spaced from the ridge such that the capacitance of the device is minimized.

60. An integrated optoelectrical semiconductor device as claimed in claim 59 wherein the implanted regions are spaced from the ridge by a maximum of about 1 μm.

61. An integrated optoelectrical semiconductor device as claimed in claim 59 wherein the implanted regions are spaced from the ridge by a maximum of about 0.5 μm.

62. An integrated optoelectrical semiconductor device as claimed in claim 59 wherein the implanted regions are spaced from the ridge by a maximum of about 0.25 μm.

63. An integrated optoelectronic semiconductor device as claimed in claim 57, wherein the modulator is an electroabsorption modulator.

64. An integrated optoelectronic semiconductor device as claimed in claim 63, wherein the laser is a distributed feedback laser or a tunable laser.

65. An integrated optoelectronic semiconductor device as claimed in claim 53, wherein the active layer of the laser and/or semiconductor optical amplifier is substantially the same as the active layer of the modulator.

66. An integrated optoelectronic semiconductor device as claimed in claim 65, wherein the ridge waveguide geometry of the laser and/or semiconductor optical amplifier is substantially the same as the ridge waveguide geometry of the modulator.

67. An integrated optoelectronic semiconductor device as claimed in claim 66, wherein the epitaxial structure of the laser and/or semiconductor optical amplifier is substantially the same as the epitaxial structure of the modulator.

68. An integrated optoelectronic semiconductor device as claimed in claim 67, wherein the active layer of the laser and/or semiconductor optical amplifier comprises a bulk active layer.

69. An integrated optoelectronic semiconductor device as claimed in claim 67, wherein the active layer of the laser and/or semiconductor optical amplifier of the laser comprises a multiple quantum well structure.

70. An optoelectronic device, the optoelectronic device comprising:
a semiconductor substrate;
an active layer on the substrate; and
a doped layer on the active layer, the doped layer having a ridge adapted to guide optical energy in the active layer, said ridge defined by adjacent shallow etched regions of the doped layer, wherein at least a portion of said doped layer is adapted for reverse-biased operation and the shallow etched regions within said at least a portion of said doped layer are ion implanted such that the capacitance of the device is reduced.

71. An optoelectronic device as claimed in claim 70, wherein said portion adapted for reverse-biased operation, comprises an electroabsorption modulator.

72. An optoelectronic device as claimed in claim 71, wherein said optoelectronic device further comprises a laser.

73. An optoelectronic device as claimed in claim 72, wherein said optoelectronic device further comprises a semiconductor optical amplifier.

74. An optoelectronic device as claimed in claim 73, wherein said modulator and said laser and/or semiconductor optical amplifier are monolithically integrated.

75. An optoelectronic device as claimed in claim 74, wherein the laser is a distributed feedback laser.

76. An optoelectronic device as claimed in claim 74, wherein the laser is a tunable laser.

77. An optoelectronic device as claimed in claim 76, wherein the active layer of said laser and/or semiconductor optical amplifier and the active layer of said modulator have a common epitaxial structure.

78. An optoelectronic device as claimed in claim 77, wherein the active layer of said laser and/or semiconductor optical amplifier comprises a bulk active layer.

79. An optoelectronic device as claimed in claim 77, wherein the active layer of said laser and/or semiconductor optical amplifier comprises a multiple quantum well structure.

80. An optoelectronic device as claimed in claim 79, in which the output of the device comprises a curved waveguide adjoining the output facet of the device and/or an anti-reflection coating on the output facet.

81. An optoelectronic device as claimed in claim 80, wherein said portion adapted for reverse-biased operation comprises any of a Mach-Zehnder modulator, a concatenated series of Mach-Zehnder modulators, a phase modulator, or a self-electro-optic effect device.
